(19) United States
(12) Patent Application Publication
(10) Pub. No.: US 2022/0299674 A1
(43) Pub. Date: Sep. 22, 2022

(54) SUPERCONDUCTING GRAVITY GRADIOMETER AND SENSITIVITY IMPROVEMENT METHOD THEREOF

(71) Applicant: HUAZHONG UNIVERSITY OF SCIENCE AND TECHNOLOGY, Hubei (CN)

(72) Inventors: Xiangdong LIU, Hubei (CN); Xikai LIU, Hubei (CN); Dong MA, Hubei (CN); Lulu WANG, Hubei (CN)

(73) Assignee: HUAZHONG UNIVERSITY OF SCIENCE AND TECHNOLOGY, Hubei (CN)

(21) Appl. No.: 17/629,414

(22) PCT Filed: Jun. 23, 2020
(86) PCT No.: PCT/CN2020/097619

§ 371 Date: Jan. 24, 2022

(30) Foreign Application Priority Data
Dec. 13, 2019 (CN) 201911284211.1

(51) Int. Cl. G01V 7/04; H01L 39/08

(52) U.S. Cl. CPC G01V 7/04; H01L 39/08

(57) ABSTRACT

The invention discloses a superconducting gravity gradiometer and a sensitivity improvement method thereof including a pair of superconducting test masses, a pair of negative-stiffness superconducting coils, a pair of positive-stiffness superconducting coils, and a superconducting circuit coupling the test masses into two-degree-of-freedom superconducting magnetic spring oscillators. Superconducting wires are used to connect the negative-stiffness superconducting coils in series to form a superconducting loop, the differential mode stiffness of the two-degree-of-freedom superconducting magnetic spring oscillators is reduced, and the ratio of the common mode stiffness to the differential mode stiffness is increased. When using the method of the invention to configure the magnetic spring oscillator of a superconducting gravity gradiometer, when configuring a vertical diagonal component superconducting gravity gradiometer with a full magnetic suspension for the test mass, the sensitivity of gradient measurement is significantly improved.

### TECHNOLOGY FIELD

The invention relates to the technical field of gravity measurement, and more specifically, to a superconducting gravity gradiometer and a method for improving the sensitivity of the superconducting gravity gradiometer.

### DESCRIPTION OF RELATED ART

Superconducting gravity gradiometers are time-varying gravity gradient measuring instruments configured by using superconductivity. A superconducting gravity gradiometer works at 4.2K liquid helium temperature and has the advantages of low inherent noise, high resolution, stable grid value, and so on. An aerial superconducting gravity gradiometer, which aims at mineral resource exploration, has the potential to break through the resolution limit of normal temperature gravity gradiometer instruments and is expected to become an important tool for deep resource exploration.

A typical configuration method fora superconducting gravity gradiometer is to use the magnetic interaction between the superconductor current-carrying coil and the superconducting test mass, through a superconducting circuit, a pair of superconducting test masses placed separately are coupled into two-degree-of-freedom magnetic spring oscillators, and the oscillator motion can be decomposed into two natural modes, the common mode and the differential mode. By measuring the differential mode displacement of the oscillator, the change in gravity gradient over time is given.

For the configuration of the coupled magnetic spring oscillator of the gradiometer, the differential mode stiffness is expected to be small, and the common mode stiffness is expected to be large. Gravity gradients are measured in the form of differential gravitational acceleration. Small differential mode stiffness means that the transfer function from a gravity gradient to a differential displacement is large, which contributes to improving the sensitivity and resolution of the instrument. On the motion platform, the motion acceleration of the platform is sensed by the instrument in the form of common mode acceleration, which needs to be subtracted by the differential. The large common mode stiffness means that the instrument is insensitive to platform motion, which contributes to improving the common mode rejection ratio of the instrument, and the interference of instrument installation platform vibration on gradient measurement is weakened.

In the superconducting gravity gradiometer, many factors limit the improvement of the ratio of the common mode to the differential mode stiffness. For example, in a full-magnetic levitation superconducting gravity gradiometer that measures the test mass of the vertical diagonal component of the gravity gradient, the magnetic repulsion between the superconducting coil and the test mass needs to be large enough to offset the gravity of the test mass, thereby suspending the test mass. Limited by this factor, the inherent frequency of the differential mode in the prior art is generally greater than 10 Hz, and the ratio of the common mode stiffness to the differential mode stiffness is also small.

### SUMMARY

In view of the defects of the prior art, the invention aims at solving the technical problem of the limited improvement of the ratio of the common mode stiffness to differential mode stiffness of a current superconducting gravity gradiometer, which leads to little improvement of the sensitivity and resolution of the gravity gradiometer.

In order to achieve the aim, in the first aspect, the invention provides a superconducting gravity gradiometer including two groups of superconducting magnetic spring oscillators and a superconducting circuit.

Each group of the superconducting magnetic spring oscillators includes a densely wound disk-type superconducting coil, a test mass, a superconducting solenoid coil and a coil bobbin; the test mass is a semi-closed superconducting cylinder with an opening on a bottom thereof; the coil bobbin is disposed below the test mass; the single-layer densely wound disk-type superconducting coil is wound on a top of the coil bobbin, and the superconducting solenoid coil is wound on a bottom of the coil bobbin; magnetic repulsion between the single-layer densely wound disc-type superconducting coil and the superconducting solenoid coil and the test mass balances gravity of the test mass, and the test mass is magnetically levitated; the magnetic repulsion is a function of displacement of the test mass, and a resultant force of a magnetic force and gravity on the test mass has a property of restoring force, configuring the superconducting magnetic spring oscillator.

Vertical magnetic repulsion force exerted by the single-layer densely wound disc-type superconducting coil on the test mass changes in proportion to the displacement of the test mass from a balance position, and a change direction is opposite to a displacement direction, which contributes positive stiffness to the superconducting magnetic spring oscillator; some magnetic field lines of the superconducting solenoid coil are in a compressed state in an enclosed space of the test mass, some magnetic field lines of the superconducting solenoid coil are in an expanded state outside the enclosed space of the test masses, vertical magnetic repulsion force exerted by the superconducting solenoid coil on the test mass changes in proportion to the displacement of the test mass from the balance position, and the change direction is the same as the displacement direction, which contributes negative stiffness to the superconducting magnetic spring oscillator; the stiffness of the superconducting magnetic spring oscillator is adjusted by a current of the single-layer densely wound disk-type superconducting coil and a current of the superconducting solenoid coil.

The superconducting circuit is connected to the densely wound disk-type superconducting coils and the superconducting solenoid coils of the two groups of superconducting magnetic spring oscillators to form a superconducting loop through superconducting wires, so as to couple the two groups of superconducting magnetic spring oscillators into two-degree-of-freedom spring oscillators to configure the superconducting gravity gradiometer; a ratio of common mode stiffness to differential mode stiffness of the superconducting gravity gradiometer is greater than a ratio of common mode stiffness to differential mode stiffness of a superconducting gravity gradiometer without superconducting solenoid coils.

Optionally, common mode stiffness k_{c} and differential mode stiffness k_{d} of the superconducting gravity gradiometer each are expressed by:

$$\{ \begin{matrix}{K}_{d} = - \frac{{i}_{0}^{2}}{2} \frac{{d}^{2} l ( z )}{d {z}^{2}} - \frac{{I}_{0}^{2}}{2} \frac{{d}^{2} L ( z )}{d {z}^{2}} + {( \frac{d L ( z )}{d z} )}^{2} \frac{{L}_{p} {I}_{0}^{2}}{{L}_{0} + 2 {L}_{p}} \\ {K}_{c} = - \frac{{i}_{0}^{2}}{2} \frac{{d}^{2} l ( z )}{d {z}^{2}} - \frac{{I}_{0}^{2}}{2} \frac{{d}^{2} L ( z )}{d {z}^{2}} + {\frac{{i}_{0}^{2}}{{l}_{0}} [ \frac{d l ( z )}{d z} ]}^{2} + {( \frac{d L ( z )}{d z} )}^{2} \frac{{I}_{0}^{2}}{{L}_{0}}\end{matrix}$$

L₀ and I₀ respectively represent effective inductance and superconducting current intensity of a positive stiffness single-layer densely wound disk-type superconducting coil in a balance position, I₀ and i₀ respectively represent effective inductance and superconducting current intensity of a negative stiffness superconducting solenoid coil in the balance position, l(z) represents effective inductance of the negative stiffness superconducting solenoid coil changing with the displacement of the test mass, L(z) represents effective inductance of the single-layer densely wound disk-type superconducting coil changing with the displacement of the test mass, Lₚ, represents the inductance connected to a middle branch of the superconducting circuit, and z represents the displacement of the test mass relative to the balance position.

Optionally, d²L(z)/dz²<0; d²l(z)/dz²>0.

Optionally, the superconducting gravity gradiometer further includes a frame. The frame is used to be connected to the coil bobbins of two groups of superconducting magnetic spring oscillators vertically.

Optionally, both the densely wound disk-type superconducting coil and the superconducting solenoid coil include multiple groups of superconducting coils.

In a second aspect, the invention provides a sensitivity improvement method of a superconducting gravity gradiometer. The superconducting gravity gradiometer includes two-degree-of-freedom superconducting magnetic spring oscillators. The method includes steps as follows.

Negative-stiffness superconducting coils are introduced in both the two-degree-of-freedom superconducting magnetic spring oscillators.

The negative-stiffness superconducting coils are connected in series to form a superconducting loop through a superconducting wire, so as to reduce differential mode stiffness of the superconducting gravity gradiometer and improve a sensitivity of the superconducting gravity gradiometer.

Optionally, each of the degree-of-freedom superconducting magnetic spring oscillators includes a densely wound disk-type superconducting coil, a test mass, and a coil bobbin; the test mass is a semi-closed superconducting cylinder with an opening on a bottom thereof; the coil bobbin is disposed below the test mass; the single-layer densely wound disk-type superconducting coil is wound on a top of the coil bobbin; magnetic repulsion between the single-layer densely wound disc-type superconducting coil and the test mass balances gravity of the test mass, and the test mass is magnetically levitated; the magnetic repulsion is a function of displacement of the test mass, and a resultant force of a magnetic force and gravity on the test mass has a property of restoring force, configuring the superconducting magnetic spring oscillator; vertical magnetic repulsion force exerted by the single-layer densely wound disc-type superconducting coil on the test mass changes in proportion to the displacement of the test mass from the balance position, and a change direction is opposite to a displacement direction, which contributes positive stiffness to the superconducting magnetic spring oscillator.

The step of introducing the negative-stiffness superconducting coils in both the two degree-of-freedom superconducting magnetic spring oscillators includes steps as follows.

Superconducting solenoid coils are wound on bottoms of the two coil bobbins. Some magnetic field lines of the superconducting solenoid coil are in a compressed state in an enclosed space of the test mass, some magnetic field lines of the superconducting solenoid coil are in an expanded state outside the enclosed space of the test masses, vertical magnetic repulsion force exerted by the superconducting solenoid coil on the test mass changes in proportion to the displacement of the test mass from the balance position, and the change direction is the same as the displacement direction, which contributes negative stiffness to the superconducting magnetic spring oscillator; the stiffness of the superconducting magnetic spring oscillator is adjusted by a current of the single-layer densely wound disk-type superconducting coil and a current of the superconducting solenoid coil.

Generally speaking, compared with the prior art, the technical solutions conceived by the invention have beneficial effects as follows.

The invention provides a superconducting gravity gradiometer and a sensitivity improvement method thereof. In the configuration of the dual test masses and two degree-of-freedom superconducting magnetic spring oscillators of the superconducting gravity gradiometer, a pair of negative-stiffness superconducting coils are introduced to interact with the superconducting test masses respectively, and the negative-stiffness superconducting coils are included in the superconducting loop in series, which effectively reduces the differential mode stiffness of the spring oscillator, improves the ratio of the common mode stiffness to the differential mode stiffness, and improves the sensitivity of the superconducting gravity gradiometer. The invention reduces the differential mode stiffness, increases the differential mode acceleration, i.e., the transfer function from the gravity gradient to the differential mode displacement, improves the sensitivity of the gradient measurement, and reduces the noise level. By improving the ratio of the common mode stiffness to the differential mode stiffness, the common mode rejection ratio is improved, and the interference of the installation platform motion acceleration on the gradient measurement is depressed.

### BRIEF DESCRIPTION OF THE DRAWINGS

FIG. 1 is a schematic view of a structure of a superconducting gravity gradiometer provided by the invention.

FIG. 2 is an equivalent schematic view of a superconducting circuit of a positive-stiffness superconducting coil of a superconducting gravity gradiometer provided by the invention.

FIG. 3 is an equivalent schematic view of a superconducting circuit of a negative-stiffness superconducting coil of a superconducting gravity gradiometer provided by the invention.

FIG. 4 is a schematic view of a relationship curve between the effective inductance of the positive-stiffness superconducting coil and the displacement provided by the invention.

FIG. 5 is a schematic view of a relationship curve between the effective inductance of the negative-stiffness superconducting coil and the displacement provided by the invention.

In all the drawings, the same reference numerals are used to denote the same elements or structures, where 1 is an upper single-layer densely wound disk-type superconducting coil, 2 is an upper test mass, 3 is an upper superconducting solenoid coil, 4 is an upper coil bobbin, 5 is lower single-layer densely wound disk-type superconducting coil, 6 is a lower test mass, 7 is a lower superconducting solenoid coil, 8 is lower coil bobbin, and 9 is a frame.

### DESCRIPTION OF THE EMBODIMENTS

In order to make the objectives, technical solutions, and advantages of the invention clearer, embodiments accompanied with drawings are described to illustrate the invention in detail below. It should be understood that the specific embodiments described here are only used to explain the invention, but not to limit the invention. In addition, the technical features involved in the various embodiments of the invention described below can be combined with each other as long as they do not conflict with each other.

Regarding that in the prior art, the two-degree-of-freedom superconducting magnetic spring oscillator includes only positive-stiffness superconducting coils, the invention proposes a configuration method for two-degree-of-freedom coupled magnetic spring oscillators with small differential mode stiffness and a large ratio of the common mode stiffness to the differential mode stiffness. The focus of the method is that the oscillator includes both a pair of negative-stiffness superconducting coils and a pair of positive-stiffness superconducting coils. The pairs of the superconducting coils interact with two superconducting test masses respectively and are connected in the same superconducting circuit. The introduction of the pair of the negative-stiffness superconducting coils significantly reduces the differential mode stiffness of the coupled spring oscillator and increases the ratio of common mode stiffness to differential mode stiffness. Using the invention to configure a superconducting gravity gradiometer sensitive probe may significantly improve the gradient measurement sensitivity and improve the ability of the gradiometer to resist external vibration interference.

The invention provides a coupled superconducting magnetic spring oscillator that can be applied to configure a superconducting gravity gradiometer. The coupled superconducting magnetic spring oscillator includes a pair of superconducting test masses, a pair of negative-stiffness superconducting coils, a pair of positive-stiffness superconducting coils, and the associated superconducting circuits coupling the pair of the test masses into a two-degree-of-freedom superconducting magnetic spring oscillators. The main point is the introduction of the negative-stiffness superconducting coils and the use of a superconducting wire to connect the negative-stiffness superconducting coils in series into a superconducting loop, the differential mode stiffness of the two-degree-of-freedom superconducting magnetic spring oscillators is reduced, and the sensitivity of gradient measurement is improved; the ratio of the common mode stiffness to the differential mode stiffness is increased to reject the interference of installation platform motion acceleration on the gradient measurement.

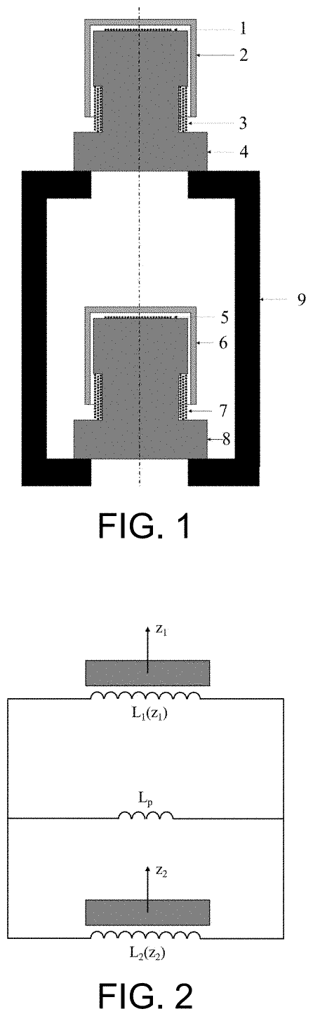

FIG. 1 is a schematic view of a structure of a superconducting gravity gradiometer provided by the invention. As shown in FIG. 1, the superconducting gravity gradiometer includes the upper single-layer densely wound disk-type superconducting coil 1, the upper test mass 2, the upper superconducting solenoid coil 3, the upper coil bobbin 4, the lower single-layer densely wound disk-type superconducting coil 5, the lower test mass 6, the lower superconducting solenoid coil 7, the lower coil bobbin 8, and the frame 9 rigidly connected to the upper coil bobbin 4 and the lower coil bobbin 8. The upper elements and the corresponding lower elements have the same parameters, and the configuration method for the upper single-layer densely wound disk-type superconducting coil and the upper superconducting solenoid coil is the same as that for the lower single-layer densely wound disk-type superconducting coil and the lower superconducting solenoid coil. The axis of the upper coil bobbin and the axis of the lower coil bobbin are aligned with each other along the plumb line, but they are vertically staggered at a certain distance, and the distance is the baseline of the gradiometer.

The materials of the test mass, the negative-stiffness superconducting coil, the positive-stiffness superconducting coil, and the superconducting circuit are all superconductors, and magnetic repulsion is formed among the test masses, the negative-stiffness superconducting coil, and the positive-stiffness superconducting coil after the negative-stiffness superconducting coil and the positive-stiffness superconducting coil store superconducting currents.

According to the principle of electromagnetics, the magnetic repulsion is

$$F ( z ) = \frac{1}{2} \frac{d {L}_{e f f} ( z )}{d z} {I}^{2} ,$$

where L_{eff} (z) is the effective inductance of the superconducting coil that depends on the displacement of the test mass, and I is the current in the coil. The positive-stiffness superconducting coil is a superconducting coil whose effective inductance L_{eff} (z) is negative to the second derivative of the test mass at the sensitive degree of freedom displacement z, that is, d²L_{eff}(z)/dz²<0; the negative-stiffness superconducting coil is a superconducting coil whose effective inductance L_{eff} (z) is positive to the second derivative of the test mass at the sensitive degree of freedom displacement z, that is, d²L_{eff}(z)/dz²>0. The effective inductance is defined as the ratio of the magnetic flux of the coil to its current. The magnetic flux of the coil refers to the sum of the magnetic flux generated by the current of the coil and the magnetic flux generated by the superconducting shielding current on the surface of the test mass interacting with the coil. The effective inductance of the superconducting coil that interacts with the test mass changes with the displacement of the test mass. The functional relationship between the two represents all characteristics of Meissner effect-based magnetic interaction between the current-carrying superconducting coil and the superconducting test mass.

The superconducting circuit is a superconducting network formed by superconducting coils connected to superconducting wires and includes single or multiple loops. The loop has the property of conservation of magnetic flux, that is Σᵢ₌₁²L_{eff}ⁱ(zᵢ)Iᵢ(z₁,z₂)+ΣⱼLⱼIⱼ(z₁, z₂)=const, where L_{eff}ⁱ(xᵢ) is the effective inductance of the i-th superconducting coil that interacts with the test mass in the loop, which is a function of the displacement of the test mass, and Iᵢ(z₁, z₂) is the current flowing through the i-th superconducting coil and is determined by the displacements of both two test masses; and Lⱼ and (z₁, z₂) are the superconducting coil that does not interact with the test mass in the loop and the superconducting current in the superconducting coil, respectively, z₁ is the displacement of the first test mass, and z₂ is the displacement of the second test mass.

It is understandable that the two superconducting test masses are disposed separately, the pairs of superconducting coils that interact with the two test masses respectively are connected to the superconducting circuit, and the motions of the two test masses are coupled through the superconducting circuit to form the two-degree-of-freedom superconducting magnetic spring oscillators. Taking a vertical oscillator as an example, as shown in FIG. 2, current-carrying superconducting coils L₁ and L₂ each are used to magnetically levitate two superconducting test masses of the same mass separately disposed in the vertical direction. The effective inductance of the superconducting coil is a function of the displacement relative to the balance position of the test mass. When the L₁ and the L₂ are connected to the same superconducting loop, according to the theory of magnetic flux conservation in the superconducting loop, one of the test masses is displaced, and the current in the superconducting coil interacting with the other test mass may change accordingly. Therefore, the motions of the two test masses are coupled with each other through the superconducting circuit to form the two-degree-of-freedom spring oscillators. Regardless of the damping, after the Fourier transform, the dynamic equation of the test masses may be expressed as follows.

$$\{ \begin{matrix}- m {ω}^{2} {z}_{1} + {k}_{11} {z}_{1} + {k}_{12} {z}_{2} = - m [ {g}_{1} ( ω ) - a ( ω ) ] \\ - m {ω}^{2} {z}_{2} + {k}_{22} {z}_{2} + {k}_{21} {z}_{1} = - m [ {g}_{2} ( ω ) - a ( ω ) ]\end{matrix} \qquad ( 1 )$$

In the equation, m is the mass, ω is the angular frequency, g₁ and g₂ are the time-varying gravitational acceleration at the center of mass of the upper and the lower test masses respectively, a is the installation platform motion acceleration, and k is the stiffness parameter of the system spring oscillator, where i=1, 2 and j=1, 2. When i=j, k represents the stiffness provided by the single-layer densely wound superconducting coil and the superconducting solenoid coil that directly interact with the test mass i; when i≠j, kᵢⱼ represents the single-layer densely wound superconducting coil and superconducting solenoid coil interacting with the i-th test mass, which are coupled through the superconducting circuit to provide the stiffness of the j-th test mass. In the design of the gradiometer, the parameters of the two test masses are generally required to be the same, and the parameters of the test masses are the same as the parameter of the magnetic interaction of the superconducting coil. The superconducting circuit with reference to the two test masses is symmetrical, which is called an ideal match, and meanwhile, k₁₁=k₂₂, and K₁₂=k₂₁. A coordinate transformation is performed, let the differential mode displacement z_{d}=z₁-z₂ and the common mode displacement z_{c}=(z₁+z₂)/2, and the solution to the dynamic equations is as follows.

$$\{ \begin{matrix}{z}_{d} = - \frac{m {a}_{d} ( ω )}{- m {ω}^{2} + {k}_{11} - {k}_{12}} \\ {z}_{c} = - \frac{m {a}_{c} ( ω )}{- m {ω}^{2} + {k}_{11} + {k}_{12}}\end{matrix} \qquad ( 2 )$$

In the equation, a_{d}(ω)=g₁(ω)−g₂(ω), called differential mode acceleration, includes the information of the time-varying gravity gradient, and the gravity gradient is usually obtained by detecting the differential mode displacement z_{d} in the gradiometer; in the equation, a_{c}(ω)=a(ω)+[g₁(ω)+g₂(ω)]/2, called common mode acceleration, includes the platform motion acceleration. According to equation (2), (k₁₁-k₁₂) is the differential mode stiffness, and (k₁₁+k₁₂)/2 is the common mode stiffness. Generally, the spring oscillator of the gradiometer is expected to have smaller differential mode stiffness to obtain a high sensitivity of gravity gradient measurement. Generally, the gradiometer is expected to have larger common mode stiffness to improve the common mode rejection ratio, and this is because errors occur inevitably in processing and manufacturing. A small amount of common mode displacement is mixed into the differential mode displacement detected by the gradiometer. The greater the common mode stiffness, the fewer common mode displacement signals mixed in, and the greater the ability of the gradiometer to resist the interference of the installation platform motion acceleration.

Taking the superconducting circuit shown in FIG. 2 as an example, a superconducting persistent current is injected into the superconducting circuit so that the current in the coils L₁ and L₂ is I₀, the test masses are in the balance position, and there is no current in a middle branch Lₚ. The theory of magnetic flux conservation in the superconducting circuit requires the current in each of the superconducting coils to satisfy the equations as follows at any time thereafter.

$$\{ \begin{matrix}{L}_{1} ( {z}_{1} ) {I}_{1} ( {z}_{1} , {z}_{2} ) + {L}_{p} {I}_{p} ( {z}_{1} , {z}_{2} ) = {L}_{0} {I}_{0} \\ {L}_{2} ( {z}_{2} ) {I}_{2} ( {z}_{1} , {z}_{2} ) - {L}_{p} {I}_{p} ( {z}_{1} , {z}_{2} ) = {L}_{0} {I}_{0} \\ {I}_{1} ( {z}_{1} , {z}_{2} ) + {I}_{p} ( {z}_{1} , {z}_{2} ) = {I}_{2} ( {z}_{1} , {z}_{2} )\end{matrix} \qquad ( 3 )$$

In the equation, L₀ is the effective inductance of the superconducting coils L₁ and L₂ when the test masses are in the balance position. L₁(z₁) and L₂(z₂) are the functional relationships of the effective inductance of the two superconducting coils changing with the displacement of the test masses interacting with the two superconducting coils, respectively. In the case of ideal matching, the parameters of the pair of superconducting coils are the same, and L₀ and I₀ can be used to represent the effective inductance and superconducting current intensity of the superconducting coil interacting with the test masses in the balance position, and there is dL₁(z₁)/dz₁=dL₂(z₂)/dz₂, which is expressed as dL(z)/dz hereinafter. I₁(z₁,z₂),I₂(z₁,z₂), and Iₚ(z₁,z₂) are the currents in the superconducting coils L₁, L₂, and Lₚ, respectively when the two test masses are displaced. By equation (3), I₁(z₁,z₂) and I₂(z₁,z₂) can be obtained.

As mentioned, the magnetic force between the superconducting coils and the test masses is expressed by

$$F ( z ) = \frac{1}{2} \frac{d {L}_{e f f} ( z )}{d z} {I}^{2} .$$

Specifically, when the superconducting coils interacting with the two test masses are connected to form a superconducting loop, the magnetic forces on the two test masses are expressed as follows.

$$\{ \begin{matrix}{F}_{1} ( {z}_{1} , {z}_{2} ) = \frac{1}{2} {\frac{d L ( z )}{d z} [ {I}_{1} ( {z}_{1} , {z}_{2} ) ]}^{2} \\ {F}_{2} ( {z}_{1} , {z}_{2} ) = \frac{1}{2} {\frac{d L ( z )}{d z} [ {I}_{2} ( {z}_{1} , {z}_{2} ) ]}^{2}\end{matrix} \qquad ( 4 )$$

Correspondingly, the stiffness coefficient of the two-degree-of-freedom spring oscillators is expressed as follows.

$$\{ \begin{matrix}{k}_{11} = - \frac{\partial }{\partial {z}_{1}} {F}_{1} ( {z}_{1} , {z}_{2} ) \\ {k}_{22} = - \frac{\partial }{\partial {z}_{2}} {F}_{2} ( {z}_{1} , {z}_{2} ) \\ {k}_{12} = {k}_{21} = - \frac{\partial }{\partial {z}_{2}} {F}_{1} ( {z}_{1} , {z}_{2} ) = - \frac{\partial }{\partial {z}_{1}} {F}_{2} ( {z}_{1} , {z}_{2} )\end{matrix} \qquad ( 5 )$$

From equation (5), the stiffness coefficient of the two-degree-of-freedom spring oscillators shown in FIG. 2 near the balance position can be given as follows.

$$\{ \begin{matrix}{k}_{11} = {k}_{22} = {( \frac{d L ( z )}{d z} )}^{2} \frac{( {L}_{p} + {L}_{0} ) {I}_{0}^{2}}{{L}_{0} ( {L}_{0} + 2 {L}_{p} )} - \frac{{I}_{0}^{2}}{2} \frac{{d}^{2} L ( z )}{d {z}^{2}} \\ {k}_{12} = {k}_{21} = {( \frac{d L ( z )}{d z} )}^{2} \frac{{L}_{p} {I}_{0}^{2}}{{L}_{0} ( {L}_{0} + 2 {L}_{p} )}\end{matrix} \qquad ( 6 )$$

The differential mode stiffness k_{d} and the common mode stiffness k_{c} each are expressed as follows.

$$\{ \begin{matrix}{k}_{d} = - \frac{{I}_{0}^{2}}{2} \frac{{d}^{2} L ( z )}{d {z}^{2}} + {( \frac{d L ( z )}{d z} )}^{2} \frac{{I}_{0}^{2}}{{L}_{0} + 2 {L}_{p}} \\ {k}_{c} = - \frac{{I}_{0}^{2}}{2} \frac{{d}^{2} L ( z )}{d {z}^{2}} + {( \frac{d L ( z )}{d z} )}^{2} \frac{{I}_{0}^{2}}{{L}_{0}}\end{matrix} \qquad ( 7 )$$

For a positive-stiffness superconducting coil, the second derivative of the effective inductance to the displacement of the test mass is less than zero, that is, d²L(z)/dz²<0. Equation (7) shows that the common mode stiffness is always greater than the differential mode stiffness, and the difference is determined by the last term of the k_{d} expression and the k_{c} expression.

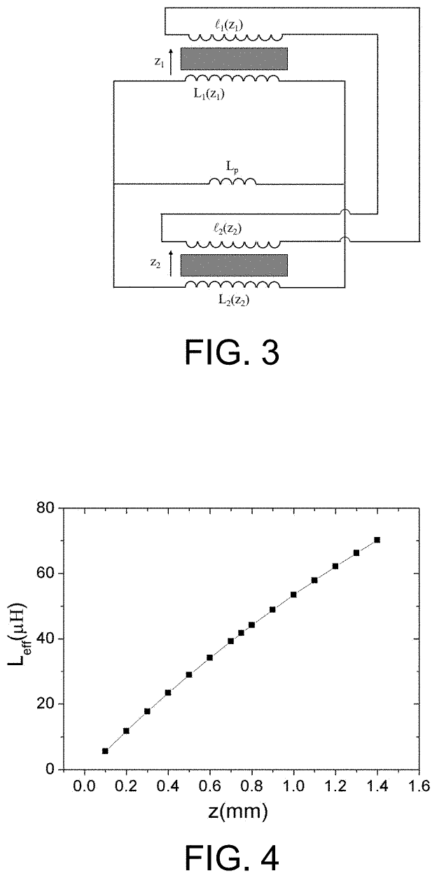

It is understandable that with the introduction of the negative-stiffness superconducting coils that interact with the two test mass, respectively, the use of superconducting wires connected to two coils in series to form a superconducting loop, and the two-degree-of-freedom superconducting magnetic spring oscillators configured by the positive stiffness coils, the differential mode stiffness can be effectively reduced, and the ratio of the common mode stiffness to the differential mode stiffness is increased. Taking two vertical degree-of-freedom oscillators as an example again, a pair of negative-stiffness superconducting coils each interacting with the two superconducting test masses are added on the basis of FIG. 2, and the negative stiffness coils are connected in series to form a superconducting loop, as shown in FIG. 3. Note that the relative positions of the superconducting coils and the test masses in FIG. 3 is not of practical significance. The drawing only illustrates that all the superconducting coils interact with the superconducting test masses. Since the positive stiffness coils and the negative stiffness coils interact with the superconducting test masses, the total stiffness coefficient of the oscillator is the sum of the stiffness coefficients provided by the interaction of the two types of coils with the test masses, respectively. The contribution of the negative stiffness coil to the stiffness coefficient is expressed as follows.

$$\{ \begin{matrix}{k}_{11}^{′} = {k}_{22}^{′} = - \frac{{i}_{0}^{2}}{2} \frac{{d}^{2} l ( z )}{d {z}^{2}} + {\frac{{i}_{0}^{2}}{2 {l}_{0}} [ \frac{d l ( z )}{d z} ]}^{2} \\ {k}_{12}^{′} = {k}_{21}^{′} = {\frac{{i}_{0}^{2}}{2 {l}_{0}} [ \frac{d l ( z )}{d z} ]}^{2}\end{matrix} \qquad ( 8 )$$

In the equation, kᵢⱼ′ is the stiffness provided by the two superconducting solenoid coils, where i=1, 2 and j=1, 2. When i=j, kᵢⱼ′ represents the stiffness provided by the superconducting solenoid coil that directly interacts with the i-th test mass; when i≠j, kᵢⱼ′ represents that the superconducting solenoid coil interacting with the i-th test mass is coupled through the superconducting circuit to provide the stiffness of the j-th test mass, l(z) is the effective inductance of the negative-stiffness superconducting coil changing with the displacement of the test mass, l₀ and i₀ are the effective inductance and superconducting current intensity of the negative-stiffness superconducting coil where the test mass is in the balance position, respectively. The total stiffness coefficient of the spring oscillator is expressed as follows.

$$\{ \begin{matrix}{K}_{11} = {K}_{22} = - \frac{{I}_{0}^{2}}{2} \frac{{d}^{2} L ( z )}{d {z}^{2}} - \frac{{i}_{0}^{2}}{2} \frac{{d}^{2} l ( z )}{d {z}^{2}} + {( \frac{d L ( z )}{d z} )}^{2} \frac{( {L}_{p} + {L}_{0} ) {I}_{0}^{2}}{{L}_{0} ( {L}_{0} + 2 {L}_{p} )} + {\frac{{i}_{0}^{2}}{2 {l}_{0}} [ \frac{d l ( z )}{d z} ]}^{2} \\ {K}_{12} = {K}_{21} = {( \frac{d L ( z )}{d z} )}^{2} \frac{{L}_{p} {I}_{0}^{2}}{{L}_{0} ( {L}_{0} + 2 {L}_{p} )} + {\frac{{i}_{0}^{2}}{2 {l}_{0}} [ \frac{d l ( z )}{d z} ]}^{2}\end{matrix} \qquad ( 9 )$$

After introducing the negative-stiffness superconducting coils, the differential mode stiffness and common mode stiffness of the oscillator are expressed as follows.

$$\{ \begin{matrix}{K}_{d} = - \frac{{i}_{0}^{2}}{2} \frac{{d}^{2} l ( z )}{d {z}^{2}} - \frac{{I}_{0}^{2}}{2} \frac{{d}^{2} L ( z )}{d {z}^{2}} + {( \frac{d L ( z )}{d z} )}^{2} \frac{{L}_{p} {I}_{0}^{2}}{{L}_{0} + 2 {L}_{p}} \\ {K}_{c} = - \frac{{i}_{0}^{2}}{2} \frac{{d}^{2} l ( z )}{d {z}^{2}} - \frac{{I}_{0}^{2}}{2} \frac{{d}^{2} L ( z )}{d {z}^{2}} + {\frac{{i}_{0}^{2}}{{l}_{0}} [ \frac{d l ( z )}{d z} ]}^{2} + {( \frac{d L ( z )}{d z} )}^{2} \frac{{I}_{0}^{2}}{{L}_{0}}\end{matrix} \qquad ( 10 )$$

Compared with the equation (7) without the negative-stiffness superconducting coil, the first term of the K_{d} expression is added in the differential mode stiffness. The negative-stiffness superconducting coil has the property of d²l(z)/dz²>0, and the differential mode stiffness may be decreased after the negative-stiffness superconducting coil is added. The current i₀ of the negative-stiffness superconducting coil is adjusted so that the differential mode stiffness of the oscillator is a smaller positive value. Positive stiffness is the basic condition for forming a spring oscillator. After adding the negative-stiffness superconducting coil, the first term and the third term of the K_{c} expression are added in the common mode stiffness of the oscillator. The first term is negative, which is equal to the decrease of the differential mode stiffness, and the third term is always positive, indicating that even if the common mode stiffness becomes smaller, the decrease value is always less than the decrease value of the differential mode stiffness. When without the introduction of the negative-stiffness superconducting coils, the common mode stiffness is always greater than the differential mode stiffness. Therefore, after the introduction of the negative-stiffness superconducting coils, the ratio of the common mode stiffness to the differential mode stiffness of the spring oscillator is always increased.

Optionally, under the guidance of equation (10), the superconducting currents in the negative-stiffness superconducting coil and the positive-stiffness superconducting coil can be adjusted to meet different design requirements.

Optionally, both the negative-stiffness superconducting coil and the positive-stiffness superconducting coil may include multiple groups of superconducting coils.

Optionally, the superconducting circuit connected to the positive-stiffness superconducting coil may have a form different from the form shown in FIG. 2. In the superconducting loop where the negative-stiffness superconducting coil is connected as shown in FIG. 3, superconducting coils that do not interact with the test masses can be further connected in series.

Optionally, according to the method of the invention, the positive stiffness coil group and the negative stiffness coil group can be used to provide a vertical magnetic force, the gravity on the test mass is offset, and both the test masses are levitated. As shown in FIG. 1, the vertical magnetic spring oscillator of the superconducting gravity gradiometer with the vertical diagonal component T_{zz} is configured, and the time-varying gravity gradient value is obtained by detecting the differential mode displacement of the oscillator. The introduction of the negative-stiffness superconducting coils can overcome the technical defect of the lower limit of the differential mode stiffness when the positive stiffness coil is used alone to levitate the test masses, the differential mode stiffness is significantly reduced, the ratio of the common mode stiffness to the differential mode stiffness is improved, and thereby the sensitivity of the gradient measurement is improved and the common mode rejection ratio is improved.

Specifically, the gravity gradient tensor has 5 independent components, and the vertical diagonal component T_{zz} represents the rate of the change of gravitational acceleration in the vertical direction. The signal of the component is large, and the aviation superconducting gravity gradiometer T_{zz} has important application prospects in the field of resource exploration.

Optionally, a coupled superconducting magnetic spring oscillator with other degrees of freedom may be configured by introducing negative-stiffness superconducting coils to measure different components in the gravity gradient tensor.

Specifically, the test mass is a superconductor cylinder with a sealing cover at the upper end, a single-layer densely wound disk-type superconducting coil is disposed adjacently under the inner cover of the cylinder, the outer diameter of the superconducting solenoid coil is slightly less than the inner diameter of the test mass cylinder, and the superconducting solenoid coil is coaxially disposed at the opening of the test mass cylinder. Appropriate geometric parameters are chosen, the single-layer densely wound disk-type superconducting coil is a positive-stiffness superconducting coil, and the superconducting solenoid coil is a negative-stiffness superconducting coil.

Specifically, a 36^{#}niobium wire is used to wind the densely wound single-layer disc coil 110 turns, the test mass is a circular cylinder with an inner diameter of 47.5 mm, and the finite element calculation result of the dependence curve of the effective inductance of the coil on the test mass displacement z is shown as FIG. 4. The curve is a concave function, and the second derivative d²L_{eff}(z)/dz²<0 is a positive-stiffness superconducting coil.

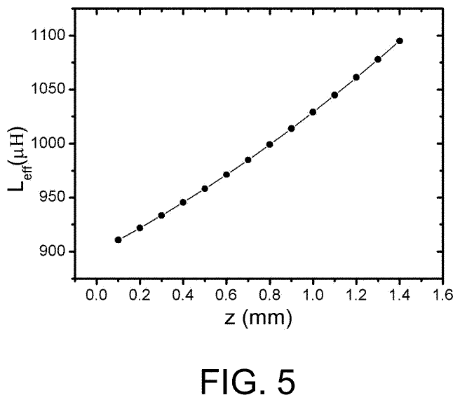

Specifically, a same size of cylindrical niobium superconducting test mass is used. A superconducting solenoid coil is coaxially disposed at the opening end of the test mass, the solenoid is formed by densely winding a σ45 bobbin with 36^{#}niobium wire 4 layers×50 turns, the superconducting solenoid coil is coaxially disposed with the test mass, the upper part of the coil winding is disposed in the test mass cylinder, and the lower part protrudes 2 mm from the lower end of the test mass. The finite element numerical calculation method is used. The dependence curve of the effective inductance of the coil on the displacement z of the test mass is obtained as shown in FIG. 5. The curve is a convex function, and its second derivative d²l_{eff}(z)/dz²>0 is a negative-stiffness superconducting coil.

More specifically, for the finite element numerical calculation method with an axisymmetric structure, refer to the prior art, and the key thereof is to calculate the shielding current distribution on the surface of the superconductor. In the finite element numerical calculation, the continuously distributed shielding current on the surface of the superconductor is discretized into numerous current loops Iᵢ(i=1,2 . . . n), and the mutual inductance Mᵢⱼ(i,j=1,2 . . . n, i≠j) between any two shielding current loops, the mutual inductance Mᵢ₀(i=1,2 . . . n) between each of the shielding current loops and the superconducting coil, and the self-inductance Lᵢ(i=1,2 . . . n) of each of the shielding current loops are calculated respectively. The Meissner effect of the superconductor requires that after the current I₀ is injected into the superconducting coil, the magnetic fluxΦᵢ(i=1,2 . . . n) of the i-th shielding current loop is zero, and accordingly n equations can be listed.

$$\begin{matrix}{Φ}_{1} = {L}_{1} {I}_{1} + {M}_{10} {I}_{0} + {\sum }_{j \neq 1} {M}_{1 j} {I}_{j} = 0 \\ … \\ {Φ}_{i} = {L}_{i} {I}_{i} + {M}_{i 0} {I}_{0} + {\sum }_{j \neq 1} {M}_{i j} {I}_{j} = 0 \\ … \\ {Φ}_{n} = {L}_{n} {I}_{n} + {M}_{n 0} {I}_{0} + {\sum }_{j \neq n} {M}_{n j} {I}_{j} = 0\end{matrix} \qquad ( 11 )$$

By numerically solving the equations, the currents of the n current loops are obtained, then the total magnetic flux generated by all current loops in the superconducting coil is obtained according to Ampere's theorem, and the magnetic flux generated by the current of the superconducting coil itself is added to the total magnetic flux and then divided by the current of the superconducting coil, i.e., the effective inductance of the superconducting coil under a given test mass displacement. Under the guidance of the configuration method of the negative-stiffness superconducting coil, the finite element numerical calculation method can be used to find the structural parameters that meet the design requirements, including the geometric shape of the test mass and the geometric and electromagnetic parameters of the superconducting coil.

The spring oscillator that configures a gravity measurement inertial sensor requires to have positive stiffness. Therefore, a superconducting coil with a property of negative stiffness is required to be used in combination with a superconducting coil with a property of positive stiffness. The differential mode stiffness and the common mode stiffness of the superconducting magnetic spring oscillator are adjusted by adjusting the currents of the two types of superconducting coils, so that the oscillator can meet the application requirements.

Specifically, the content of the invention is applied to configure a superconducting gravity gradiometer with a diagonal vertical component T_{zz}. A typical method is to use superconducting coils to magnetically levitate two test masses disposed vertically separately, a superconducting circuit is used to be connected to the superconducting coils that interact with the test masses to form a superconducting loop, two-degree-of-freedom magnetic spring oscillators are configured by the coupling of the superconducting loop, and the gravity gradient is given by measuring the differential mode displacement of the oscillator.

The structure shown in FIG. 1 and the superconducting circuit shown in FIG. 3 are used to configure the two-degree-of-freedom superconducting magnetic spring oscillators. A superconducting current of 4.58 A is injected into the positive stiffness coil, a superconducting current of 2.56 A is injected into the negative stiffness coil, both superconducting coils levitate the test masses, and the two test masses of 100 grams are levitated 0.8 mm above the positive stiffness single-layer densely wound disk-type superconducting coil to configure the two-degree-of-freedom vertical superconducting magnetic spring oscillators. According to the finite element numerical calculation results, meanwhile the effective inductance of the positive-stiffness disk-type superconducting coil is L₀=44.2 μH, the first derivative of the test mass displacement is dL_{eff}(z)/dz=48.1 μH/mm, the second derivative is d²L_{eff}(z)/dz²=−17.4 μH/mm²; the effective inductance of the negative stiffness superconducting solenoid coil is 999 μH, the first derivative of the test mass displacement is dl_{eff}(z)/dz=144.7 μH/mm, and the second derivative is d²l_{eff}(z)/dz²=51.64 μH/mm². Lp is set to be 800 μH. According to the given calculation method, the differential mode stiffness of the two-degree-of-freedom spring oscillators is 42.9 N/m, the common mode stiffness is 1248.8 N/m, and the ratio of the common mode stiffness to the differential mode stiffness is 29. If the negative-stiffness superconducting coils are not introduced, the current of the positive stiffness disk-type superconducting coil is required to be increased to 6.38 A to levitate the test mass to the same height, meanwhile the differential mode stiffness of the two-degree-of-freedom spring oscillators is 411.4 N/m, the common mode stiffness is 2484.8 N/m, and the ratio of the common mode stiffness to the differential mode stiffness is 6. These calculation results clearly show that the introduction of negative-stiffness superconducting coils can significantly reduce the differential mode stiffness of the spring oscillator, and the ratio of the common mode stiffness to the differential mode stiffness is significantly improved. More systematic calculations and analyses show that under different levitation heights, or when the superconducting circuit of the positive-stiffness superconducting coil adopts different forms and parameters, the introduction of the negative stiffness superconducting levitation coils can reduce the differential mode stiffness to various degrees, and the ratio of the common mode stiffness to the differential mode stiffness is increased.

Note that those skilled in the art may understand that the superconducting solenoid coil or the single-layer densely wound disk-type coil provided in the invention is only an example of a superconducting coil. Any technical solution that uses other types of superconducting coils to implement the control of the positive and negative stiffness of the spring oscillator should fall within the protection scope of the invention.

Those skilled in the art can easily understand that the foregoing descriptions are only the preferred embodiments of the invention and are not intended to limit the invention. Any modification, equivalent replacement and improvement, and so on made within the spirit and principle of the invention shall be included in the protection scope of the invention.

1. A superconducting gravity gradiometer, comprising: two groups of superconducting magnetic spring oscillators and a superconducting circuit;
wherein each group of the superconducting magnetic spring oscillators comprises a single-layer densely wound disk-type superconducting coil, a test mass, a superconducting solenoid coil and a coil bobbin; the test mass is a semi-closed superconducting cylinder with an opening on a bottom thereof; the coil bobbin is disposed below the test mass; the single-layer densely wound disk-type superconducting coil is wound on a top of the coil bobbin, and the superconducting solenoid coil is wound on a bottom of the coil bobbin; magnetic repulsion between the single-layer densely wound disc-type superconducting coil and the superconducting solenoid coil and the test mass balances gravity of the test mass, and the test mass is magnetically levitated; the magnetic repulsion is a function of displacement of the test mass, and a resultant force of a magnetic force and gravity on the test mass has a property of restoring force, configuring the superconducting magnetic spring oscillator;
wherein vertical magnetic repulsion force exerted by the single-layer densely wound disc-type superconducting coil on the test mass changes in proportion to the displacement of the test mass from a balance position, and a change direction is opposite to a displacement direction, which contributes positive stiffness to the superconducting magnetic spring oscillator; some magnetic field lines of the superconducting solenoid coil are in a compressed state in an enclosed space of the test mass, some magnetic field lines of the superconducting solenoid coil are in an expanded state outside the enclosed space of the test masses, vertical magnetic repulsion force exerted by the superconducting solenoid coil on the test mass changes in proportion to the displacement of the test mass from the balance position, and the change direction is the same as the displacement direction, which contributes negative stiffness to the superconducting magnetic spring oscillator; the stiffness of the superconducting magnetic spring oscillator is adjusted by a current of the single-layer densely wound disk-type superconducting coil and a current of the superconducting solenoid coil; and
wherein the superconducting circuit is connected to the densely wound disk-type superconducting coils and the superconducting solenoid coils of the two groups of superconducting magnetic spring oscillators to form a superconducting loop through superconducting wires, so as to couple the two groups of superconducting magnetic spring oscillators into two degree-of-freedom spring oscillator to configure the superconducting gravity gradiometer; a ratio of common mode stiffness to differential mode stiffness of the superconducting gravity gradiometer is larger than a ratio of common mode stiffness to differential mode stiffness of a superconducting gravity gradiometer without superconducting solenoid coils.

2. The superconducting gravity gradiometer according to claim 1, wherein common mode stiffness kc and differential mode stiffness k_{d} of the superconducting gravity gradiometer each are expressed by:
$$\{ \begin{matrix}{K}_{d} = - \frac{{i}_{0}^{2}}{2} \frac{{d}^{2} l ( z )}{{dz}^{2}} - \frac{{I}_{0}^{2}}{2} \frac{{d}^{2} L ( z )}{{dz}^{2}} + {( \frac{d L ( z )}{d z} )}^{2} \frac{{L}_{p} {I}_{0}^{2}}{{L}_{0} + 2 {L}_{p}} \\ {K}_{c} = - \frac{{i}_{0}^{2}}{2} \frac{{d}^{2} l ( z )}{d {z}^{2}} - \frac{{I}_{0}^{2}}{2} \frac{{d}^{2} L ( z )}{{dz}^{2}} + {\frac{{i}_{0}^{2}}{{l}_{0}} [ \frac{d l ( z )}{d z} ]}^{2} + {( \frac{d L ( z )}{d z} )}^{2} \frac{{I}_{0}^{2}}{{L}_{0}}\end{matrix}$$
where L₀ and I₀ respectively represent effective inductance and superconducting current intensity of a positive stiffness single-layer densely wound disk-type superconducting coil in a balance position, l₀ and i₀ respectively represent effective inductance and superconducting current intensity of a negative stiffness superconducting solenoid coil in the balance position, l(z) represents effective inductance of the negative stiffness superconducting solenoid coil changing with the displacement of the test mass, L(z) represents effective inductance of the single-layer densely wound disk-type superconducting coil changing with the displacement of the test mass, Lₚ represents the inductance connected to a middle branch of the superconducting circuit, and z represents the displacement of the test mass relative to the balance position.

3. The superconducting gravity gradiometer according to claim 2, wherein d²L(z)/dz²<0; d²l(z)/dz²>0.

4. The superconducting gravity gradiometer according to claim 1, further comprising a frame;
wherein the frame is used to be connected to the coil bobbins of the two groups of superconducting magnetic spring oscillators vertically.

5. The superconducting gravity gradiometer according to claim 1, wherein both the single-layer densely wound disk-type superconducting coil and the superconducting solenoid coil comprise a plurality of groups of superconducting coils.

6. A sensitivity improvement method of a superconducting gravity gradiometer, the superconducting gravity gradiometer comprising two-degree-of-freedom superconducting magnetic spring oscillators, the method comprising steps as follows:
introducing negative-stiffness superconducting coils in both superconducting magnetic spring oscillators;
connecting the negative-stiffness superconducting coils in series to form a superconducting loop through a superconducting wire, so as to reduce differential mode stiffness of the superconducting gravity gradiometer and improve a sensitivity of the superconducting gravity gradiometer.

7. The sensitivity improvement method of the superconducting gravity gradiometer according to claim 6, wherein each of the superconducting magnetic spring oscillators comprises a densely wound disk-type superconducting coil, a test mass, and a coil bobbin; the test mass is a semi-closed superconducting cylinder with an opening on a bottom thereof; the coil bobbin is disposed below the test mass; the single-layer densely wound disk-type superconducting coil is wound on a top of the coil bobbin; magnetic repulsion between the single-layer densely wound disc-type superconducting coil and the test mass balances gravity of the test mass, and the test mass is magnetically levitated; the magnetic repulsion is a function of displacement of the test mass, and a resultant force of a magnetic force and gravity on the test mass has a property of restoring force, configuring the superconducting magnetic spring oscillator; vertical magnetic repulsion force exerted by the single-layer densely wound disc-type superconducting coil on the test mass changes in proportion to the displacement of the test mass from the balance position, and a change direction is opposite to a displacement direction, which contributes positive stiffness to the superconducting magnetic spring oscillator; and
the step of introducing the negative-stiffness superconducting coils in both superconducting magnetic spring oscillators comprises steps as follows:
winding bottoms of the two coil bobbins to form superconducting solenoid coils, wherein some magnetic field lines of the superconducting solenoid coil are in a compressed state in an enclosed space of the test mass, some magnetic field lines of the superconducting solenoid coil are in an expanded state outside the enclosed space of the test masses, vertical magnetic repulsion force exerted by the superconducting solenoid coil on the test mass changes in proportion to the displacement of the test mass from the balance position, and the change direction is the same as the displacement direction, which contributes negative stiffness to the superconducting magnetic spring oscillator; the stiffness of the superconducting magnetic spring oscillator is adjusted by a current of the single-layer densely wound disk-type superconducting coil and a current of the superconducting solenoid coil.

8. The superconducting gravity gradiometer according to claim 2, further comprising a frame;
wherein the frame is used to be connected to the coil bobbins of the two groups of superconducting magnetic spring oscillators vertically.

9. The superconducting gravity gradiometer according to claim 3, further comprising a frame;
wherein the frame is used to be connected to the coil bobbins of the two groups of superconducting magnetic spring oscillators vertically.

10. The superconducting gravity gradiometer according to claim 2, wherein both the single-layer densely wound disk-type superconducting coil and the superconducting solenoid coil comprise a plurality of groups of superconducting coils.

11. The superconducting gravity gradiometer according to claim 3, wherein both the single-layer densely wound disk-type superconducting coil and the superconducting solenoid coil comprise a plurality of groups of superconducting coils.
